(19) United States
(12) Patent Application Publication
(10) Pub. No.: US 2022/0018720 A1
(43) Pub. Date: Jan. 20, 2022

(54) SENSING JUNCTION TEMPERATURE OF POWER TRANSISTORS

(71) Applicant: DANA TM4 INC., Boucherville (CA)

(72) Inventors: Michel TULANE, Saint-Jean-sur-Richelieu (CA); Alain ST-JACQUES, St-Bruno-de-Montarville (CA); Benoit BLANCHARD ST-JACQUES, Sainte-Julie (CA); Jonathan PICHER, St-Bruno-de-Montarville (CA)

(21) Appl. No.: 16/933,867

(22) Filed: Jul. 20, 2020

(51) Int. Cl. G01K 7/22; H02P 29/68

(52) U.S. Cl. CPC G01K 7/22; G01K 2217/00; H02P 29/68

(57) ABSTRACT

A method for estimating a junction temperature of a power transistor used in an inverter, comprising measuring a temperature-dependent characteristic of a power semiconductor comprising the power transistor used in a power semiconductor module adapted for use in the inverter, and estimating the junction temperature of the power semiconductor using the mathematical relationship between junction temperature and the temperature-dependent characteristic of the power semiconductor. Measurement of the temperature-dependent characteristic and estimation of the junction temperature therefrom is free from using a discrete sensing element.

### FIELD

The present disclosure relates to estimating junction temperature of power transistors, and more particularly to sensing junction temperature of power transistors used in inverters using on-state measurements and without using discrete temperature sensing elements.

### BACKGROUND AND SUMMARY

Electric vehicles and electric hybrid vehicles make use of power electronics and electrical components that generate substantial amounts of heat during operation. Automotive electric motors used in electric vehicles and electric hybrid vehicles typically comprise one or more multiphase alternating current (AC) motor that require an inverter to use direct current (DC) power supplied by batteries. A rectifier may be required to convert AC power to DC power for charging the on-board batteries. Further, DC-to-DC converters may be required to step-up or step-down DC voltage levels within the power electronic system. The automotive inverter typically includes electronic switching components, such as high voltage/high current power transistors, that are controllably switched on and off in rapid sequence so as to provide multiphase AC to the electric motor. The power transistors generate considerable heat, requiring thermal management/thermal protection to prevent overheating and to control performance of the inverter.

The present inventors recognized that performance of the inverter controlling and supplying the motor (i.e., the output current capacity) is limited by the temperature of its semiconductor switches and that improvement in temperature estimation of the semiconductor switches is desirable for the overall performance of the inverter. However, existing state-of-the art temperature measurement for power semiconductor modules in inverter applications typically involves using discrete temperature sensing elements for providing temperature information used for operation of the power transistors (usually but not limited to Gallium Nitride FETS, Silicon carbide (SiC) MOSFETs (Metal Oxide Semiconductor field effect transistors), IGBTs (Insulated Gate Bipolar Transistors), and more). The discrete temperature sensing elements generally comprise a separate component attached (using a technique like soldering) to the power module substrate near the power transistor dies. This component is typically an NTC (negative temperature coefficient) thermistor, a PTC (positive temperature coefficient) thermistor, or an RTD (resistance temperature detector) type of device. The described temperature sensing embodiments may also be used in replacement of other methods such as infra-red temperature measurement, during product development.

The present inventors further recognized disadvantages with this type of temperature sensing scheme. First, using such discrete sensing element (e.g., a thermistor) is inaccurate regarding the absolute steady-state junction temperature of the semiconductor dies; and, second, the method is too slow to detect quick variations of the power transistor junction temperatures.

To address at least some of the aforementioned and other problems, embodiments for estimating a junction temperature of a power transistor used in an electric vehicle inverter are provided. According to a first aspect of the disclosure, methods comprise measuring a temperature-dependent characteristic of the power transistor and estimating, using a processor, the junction temperature of the power semiconductor using a transfer function comprising a mathematical relationship between junction temperature and the temperature-dependent characteristic of the power semiconductor, where measurement of the temperature-dependent characteristic and estimation of the junction temperature therefrom is free from using a discrete sensing element.

According to another aspect, the temperature-dependent characteristic is an on-state resistance (for MOSFET power transistors), and measuring the temperature-dependent characteristic comprises sampling a junction voltage of the power transistor using a junction voltage sampling circuit, sensing the drain current of the power transistor using a phase current sensor, and calculating, using the processor, the on-state resistance using the junction current and the junction voltage. According to another aspect, sampling the junction voltage of the power transistor using the junction voltage sampling circuit includes measuring the voltage difference between a drain and a source of the power transistor during the on-time of the power transistor, wherein sensing the drain current of the power transistor using the phase current sensor includes measuring the phase current (corresponding to the drain current during on-state), and wherein the on-state resistance is the on-state resistance between the drain and the source of the power transistor and is calculated as the junction voltage divided by the drain current.

According to another aspect, the temperature-dependent characteristic is an on-state resistance (for MOSFET power transistors), and measuring the temperature-dependent characteristic comprises sensing the drain current of the power transistor using a phase current sensor, detecting a peak current amplitude of the power transistor using a peak current detector, sampling a junction voltage of the power transistor using a junction voltage sampling circuit, detecting a peak conduction voltage using a peak voltage detector, and calculating, using a processor, the on-state resistance using the peak current amplitude and the peak conduction voltage. According to another aspect, the peak current amplitude and the peak conduction voltage are matched with one another using a sequencer.

According to another aspect, the temperature-dependent characteristic is a saturation voltage of the power transistor (for IGBTs power transistors), and measuring the temperature-dependent characteristic comprises sampling the junction voltage of the power transistor using a junction voltage sampling circuit. According to another aspect, sensing the collector current of the power transistor using a phase current sensor, detecting a peak current amplitude of the power transistor using a peak current detector, matching the peak current amplitude and the peak saturation voltage using a sequencer, and using the peak current amplitude and the peak saturation voltage to estimate the junction temperature of the power transistor based on the transfer function, wherein the transfer function includes junction temperature of the power transistor as a function of peak saturation voltage for the peak current amplitude or for a range of peak current amplitude that includes the peak current amplitude.

According to another aspect, sensing a junction temperature of a power transistor used in an electric vehicle inverter, the method comprising sensing a junction current of the power transistor using a phase current sensor, detecting a peak current amplitude of the power transistor using a peak current detector; sampling a junction voltage of the power transistor using a junction voltage sampling circuit, detecting a peak conduction voltage using a peak voltage detector; calculating, using a processor, an on-state resistance using the peak current amplitude and the peak conduction voltage, and estimating the junction temperature using a transfer function that maps a predetermined relationship between junction temperature and on-state resistance, wherein the peak current amplitude and the peak conduction voltage are matched with one another using a sequencer, and wherein estimation of the junction temperature is free from using a discrete sensing element.

According to another aspect, a method for sensing a junction temperature of a power transistor used in an electric vehicle inverter comprises sensing a drain or collector current of the power transistor using a phase current sensor, detecting a peak current amplitude of the power transistor using a peak current detector, sampling a junction voltage of the power transistor using a junction voltage sampling circuit; detecting a peak saturation voltage using a peak voltage detector, and estimating the junction temperature using a transfer function that maps a predetermined relationship between junction temperature and saturation voltage, wherein the peak current amplitude and the peak conduction voltage are matched with one another using a sequencer, and wherein estimation of the junction temperature is free from using a discrete sensing element. According to another aspect, the power transistor is an IGBT (insulated gate bipolar transistor), using the discrete sensing element includes the discrete sensing element being attached to a substrate comprising the IGBT or to a circuit board comprising the IGBT, and the discrete sensing element comprises one or more thermistor, NTC (negative temperature coefficient) thermistor, PTC (positive temperature coefficient) thermistor, or RTD (resistance temperature detector.

According to another aspect, a system adapted to sense a junction temperature of a power transistor used in an electric vehicle inverter comprises a junction voltage sampling circuit electrically interconnected with the power transistor in the electric vehicle inverter and adapted to sample a junction voltage of the power transistor to obtain a sampled junction voltage during an on-state of the power transistor, and a processor adapted to estimate the junction temperature of the power transistor based on the sampled junction voltage, wherein the system is free from a discrete temperature sensing element. According to another aspect, the power transistor is a MOSFET (metal-oxide semiconductor field effect transistor), and the processor is adapted to calculate an on-state junction resistance of the MOSFET and estimate the junction temperature of the MOSFET based on the sampled junction voltage and calculated on-state junction resistance.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

The accompanying drawings are incorporated herein as part of the specification. The drawings described herein illustrate embodiments of the presently disclosed subject matter, and are illustrative of selected principles and teachings of the present disclosure. However, the drawings do not illustrate all possible implementations of the presently disclosed subject matter, and are not intended to limit the scope of the present disclosure in any way.

FIG. 1 is a diagram of an automotive vehicle system that includes a traction battery, inverter, and traction motor, according to embodiments.

FIG. 2 is a block diagram of the battery, inverter, and motor shown in FIG. 1, according to embodiments.

FIG. 3 is an exemplary power module electrical schematic comprising power semiconductors in a half-bridge arrangement as may be used according to embodiments.

FIG. 4 is a perspective view of a power module illustrating an arrangement of power transistors for an inverter according to embodiments, and that includes a discrete temperature sensing element.

FIG. 5 is a functional block diagram showing exemplary components and methods for estimating junction temperature for an inverter design that includes a discrete sensing element.

FIG. 6 is a functional block diagram showing exemplary components and methods for estimating junction temperature for an inverter design according to embodiments.

FIG. 7 is a graph showing on-state resistance versus junction temperature.

FIG. 8 is a graph of saturation voltage versus junction temperature.

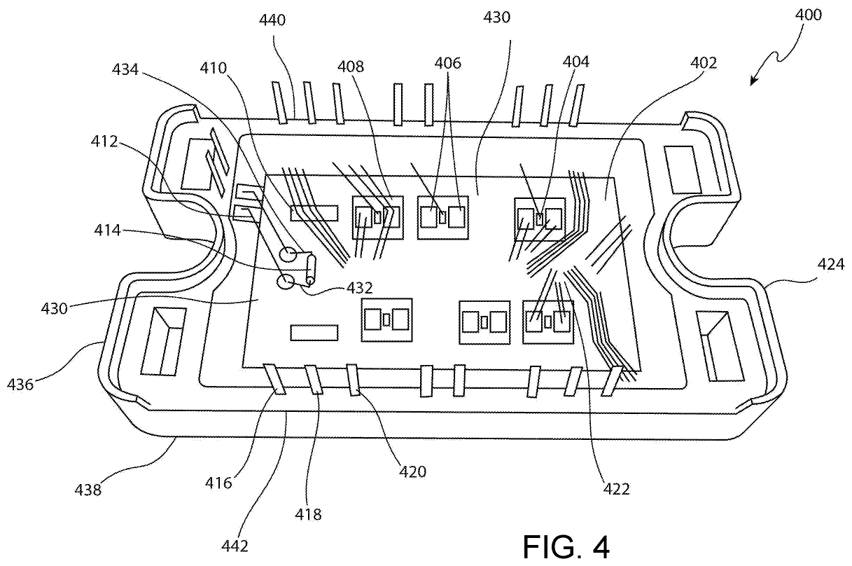

Similar reference numerals may have been used in different figures to denote similar components. FIG. 4 is shown with components in proportional size with one another, according to some embodiments

### DETAILED DESCRIPTION

It is to be understood that the invention may assume various alternative orientations and step sequences, except where expressly specified to the contrary. It is also to be understood that the specific assemblies and systems illustrated in the attached drawings, and described in the following specification are simply exemplary embodiments of the inventive concepts defined herein. Hence, specific dimensions, directions or other physical characteristics relating to the embodiments disclosed are not to be considered as limiting, unless expressly stated otherwise. Also, although they may not be, like elements in various embodiments described herein may be commonly referred to with like reference numerals within this section of the application.

As mentioned, the present inventors recognized that the performance of a traction inverter (at least in terms of output current capacity) is limited by the temperature of its semiconductor switches. The present inventors recognized that improvements in temperature estimation of the semiconductor switches are needed for improved overall performance of the inverter. With this, the present inventors set out to address the shortcomings of existing inverter designs, which involve temperature measurement for power semiconductor modules in inverter applications that employ discrete sensing elements, such as, for example, a thermistor, packaged in the power switches module (power semiconductor module) near the power transistor dies (such as the MOSFET (metal-oxide semiconductor field effect transistor) or IGBT (insulated gate bipolar transistor) dies). Namely, such discrete temperature sensing elements are inaccurate regarding the absolute steady-state junction temperature of the semiconductor dies, and sensing temperature in this way is too slow for detecting quick variations of the junction temperatures.

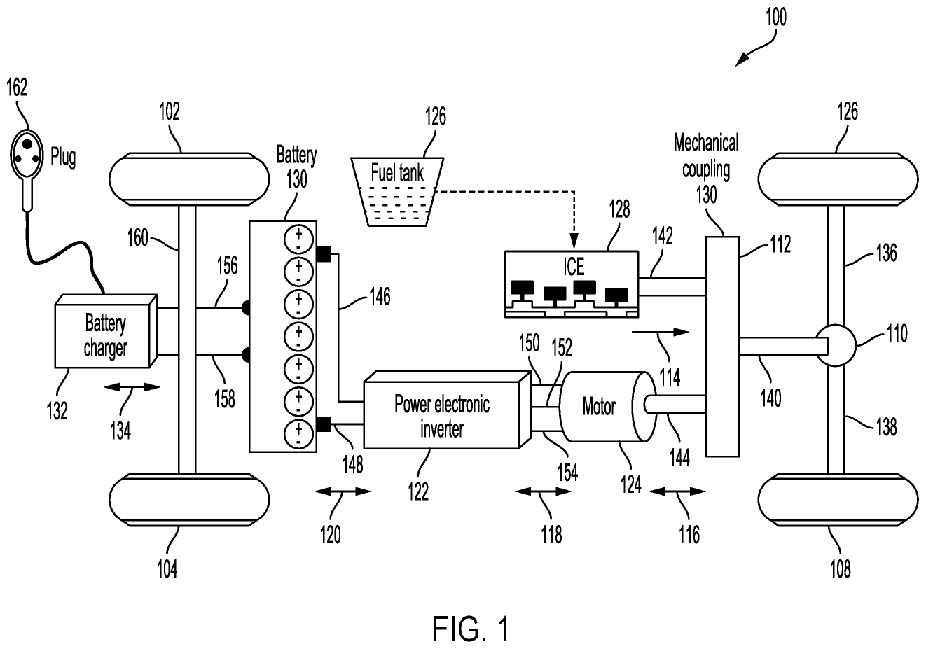

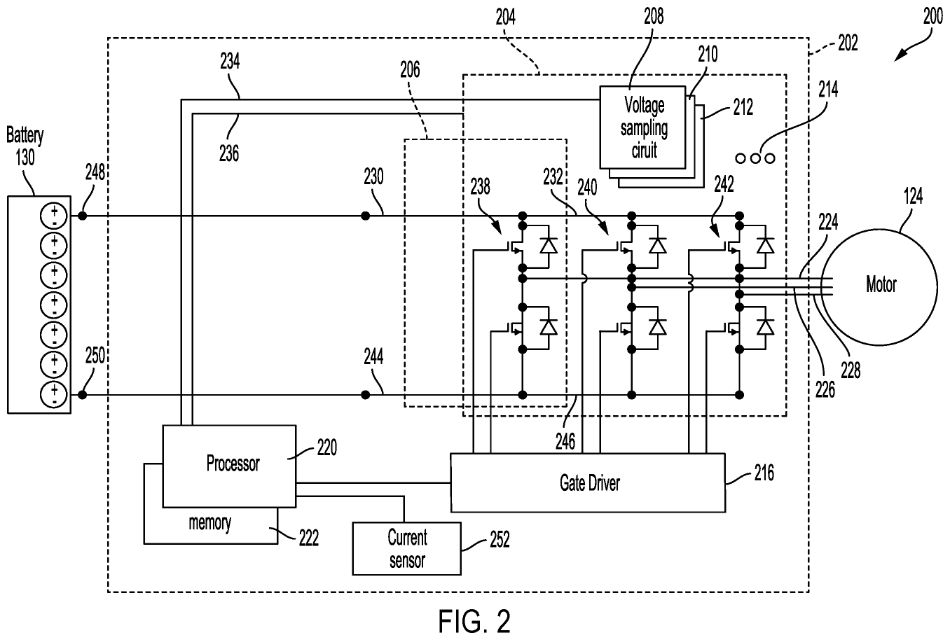

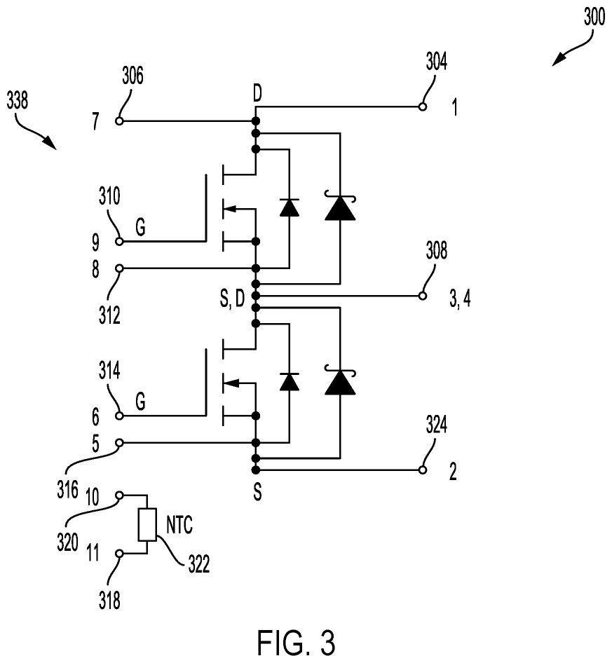

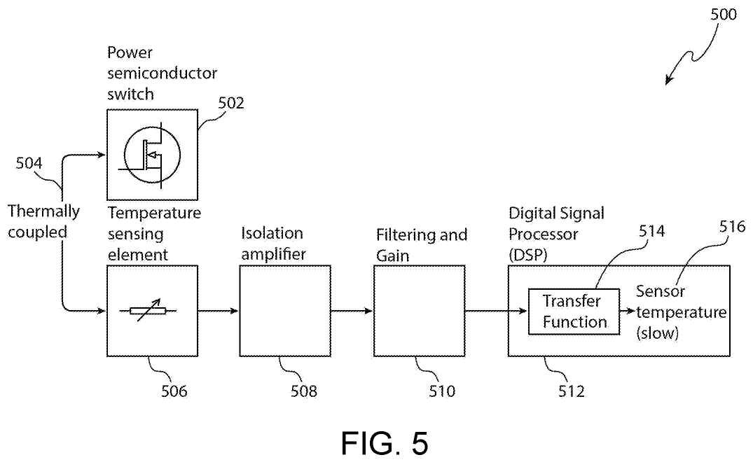

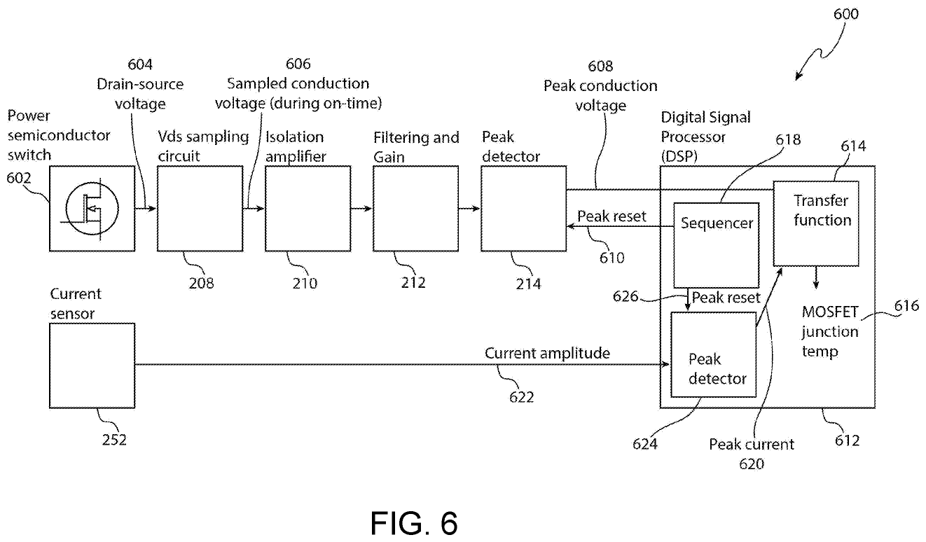

As an overview, FIG. 1 illustrates an example of a hybrid vehicle system to provide context for the described embodiments, showing a traction inverter between a traction energy storage system (battery) and a traction motor for driving the drive wheels of the vehicle. Following this, FIG. 2 presents a block diagram of a battery, inverter, and motor shown FIG. 1, according to embodiments. FIG. 3 includes an exemplary half-bridge arrangement usable in the inverter, according to embodiments. FIGS. 4 and 5 provide additional description of an inverter module, aspects of sensing junction temperature using a discrete sensing element, and temperature estimation methods therefor. FIGS. 6-8 provide exemplary components and methods for junction temperature sensing comprising measuring a temperature-dependent characteristic of the power transistors and estimating the junction temperature using a transfer function, and providing exemplary transfer function relationships between, for example, on-state resistance versus junction temperature, and saturation voltage versus temperature.

FIG. 1 illustrates a vehicle 100 comprising an inverter, such as a traction inverter 122, that exchanges or communicates electrical energy with an energy storage system (such as battery 130) and exchanges electrical energy with a motor, such as traction motor 124, that, in one direction, converts the electrical energy into mechanical energy, for example rotational motion for driving the vehicle traction system, such as may be associated with and include wheels 106, 108; and that, in another direction, convers the mechanical energy, such as from the drive wheels 106, 108, to electrical energy. The present inventors recognized the importance of improving the efficiency, cost, and other characteristics of the inverter and that improvements of the inverter comprise improving the power electronics, especially the temperature estimation of the power transistors used in the inverter. As will be described in greater detail herein, the present inventors discovered improvements in estimating the junction temperature of the power transistors may be used to maximize the amount of current that can be sent to the motor while ensuring the safe operation of the power transistors.

FIG. 1 illustrates an example hybrid vehicle system. Vehicle 100, as shown, includes a number of connected components and systems. The vehicle 100 may be charged via plug/receptacle 162, which transfers power to battery charger 132. The charger then transfers power to the energy storage system (or battery) 130 through bi-directional connection 134 comprising power linkages (or electrical conductors) 156 and 158. Power electric inverter 122 may receive power from and transfer power to the battery 130 via the bi-directional connection 120 comprising power linkages 146 and 148. The power electronic inverter 122 may likewise receive power (electrical energy) from and transfer power (electrical energy) to the electric (AC) motor 124 via bi-directional connection 118 comprising (phase current) linkages 150, 152, and 154. A fuel tank 126 provides gasoline or other fuel to the internal combustion engine (ICE) 128. Several other topologies other than the parallel topology shown in FIG. 1 may be used, including, for example, series or parallel-series. Both the electric motor and the ICE are coupled via mechanical connections 144 and 142, respectively, to a mechanical coupling system 112 which may comprise, for example, a differential and/or gear reducer and/or other mechanical couplings adapted to receive mechanical (i.e. rotating) energy from one or both of the ICE 128 and/or traction motor 124, and transfer the mechanical energy to the vehicle drive axle assembly, such as drive shaft 140, differential 110, half shafts 136 and 138, and drive wheels 106 and 108.

It may be noted that the ICE 128, as shown, typically transfers power in one direction, as indicated by connection 114. The mechanical connection 144 transfers power bi-directionally, as indicated by connection 116. The mechanical coupling then transfers the power via coupling 140 to axels 136 or 138. In some embodiments, the axels 136 and 138 may be a single axel; however, in other embodiments they may be separate half-axels connected by a joint 110. An unpowered axel 160 is located at the rear of the vehicle; however, axle 160 may be otherwise arranged and/or driven with (not shown) drive line coupling to one or more ICE and/or motor, including ICE 128 and/or AC traction motor 124. The vehicle rides on wheels 102, 104, 106, and 108; however, drive wheels 102, 104, 106, 108 may comprise other drive traction structure (e.g., track) and may comprise a different number of drive traction structures instead of the four (i.e. four drive wheels) shown.

FIG. 2 illustrates a battery-inverter-motor configuration 200, usable in vehicle 100, comprising an energy storage system such as battery 130, an inverter such as inverter 202, and a motor such as traction motor 124. The inverter 202, in some embodiments, comprises an H-bridge arrangement using three pairs of, or six, power transistors, such as pairs 238, 240, and 242, connected with positive and negative electrical connections of the energy storage system (described herein as inputs to the inverter), such as terminals 248 and 250 of the battery 130, and three phase connections (described herein as outputs of the inverter), such as phase load connections 224, 226, and 228 of traction motor 124.

Although described herein as having inputs and outputs, usually in the context of DC from the battery as inputs to the inverter and AC from the inverter as outputs from the inverter (and inputs to the motor), as mentioned and shown in FIG. 1, electrical energy generated by motor 124 may be inputs to the inverter (at AC motor phase current conductors 224, 226, and 228) with the inverter 202 providing (as outputs of the inverter 248, 250) electrical energy to the battery for charging the battery via the inverter 202.

Also with respect to the dashed boxes 202, 206, and 204 shown in FIG. 2, although various components and functionality may be described within a particular box, the boxes (i.e. 202, 206, 204) may comprise more or less than the functionality and components shown and described. The boxes are to assist in describing various components and functionality; however, the boxes do not limit which components or functionality might be included in, for example, the inverter (such as inverter 122). For example, although not shown, the inverter may comprise half-bridge boost DC-DC converter circuitry interposed between terminals 248 and 250 of the battery 130 and terminal/conductor connections 230 and 244. One skilled in the art will know that interposing such half-bridge boost DC-DC circuitry (to, for example, step up the voltage from the battery 130 to a higher voltage input going into the pairs of power transistors 238, 232, and 242) between terminals 248, 250 and conductor points 230, 244 necessarily replaces the continuity of conduction between the terminal positions shown in FIG. 2. For example, the interposed half-bridge boost DC-DC converter circuitry would replace the conductor between battery terminal 248 and terminal/conductor position 230. Optional half-bridge boost DC-DC circuitry will be further described with respect to FIG. 3.

Still with regard to the boxes 202, 204, and 206 in FIG. 2, various components and functionality may, in some embodiments, comprise components and functionality that may be realized in separable modules whereby some components and functionality are housed in a separate casing/housing, for example. In one embodiment, the inverter 122 may comprise the high voltage circuitry illustrated in FIG. 2, with some or all of the low voltage circuitry (i.e., processor 220, memory 222, gate driver 216, etc.) arranged in a separate module. As another example, in one embodiment, low voltage circuitry comprising the current sensor and isolation circuitry therefor, to, for example, provide operative (and electrically isolated) phase current sensing through the AC load conductors 224, 226, and 228, may be integrally disposed within circuit boards comprising the inverter 122 as opposed to a separately housed module (with separate casing/housing).

As shown in FIG. 2, gate driver circuitry 216, comprising low voltage circuitry isolated from the high voltage circuitry to and from the battery 130 and motor 124, is adapted to control the power transistors (or power FETs) via the six gate inputs shown within in the power transistor circuitry portion 204. Gate driver circuitry 216 may receive control signals from the processor 220, for example, to control each of the six semiconductor switching states such that, in each pair of transistors 238, 240, and 242, one transistor switch is closed (on-state, allowing current flow through the closed, high voltage/high current side of the transistor/switch) as the other transistor in the pair is open (preventing current flow through the closed transistor).

In a particular half-bridge, such as half-bridge 206, for example, one transistor in the pair (e.g., pair 238) is controllably closed while the other is controllably open such that current flows between the battery and the load (phase current conductor to the AC motor) through the closed power transistor and so that the half-bridge does not form a short between the positive conductor extending from the energy storage system/battery 130 and the negative conductor extending therefrom. In operation, the gate of each power transistor is controlled (such as by processor 220 and gate driver 216) to open and close in sequence with each of the other power transistors so as to control current flow between the battery and the motor via each of the phase current conductors 224, 226, 228. Controlling the (fast) switching of each of the power transistors in the (as shown in FIG. 2, H-bridge arrangement of six power transistors) is, therefore, of critical importance for high performance of the inverter and of the AC motor.

As shown in FIG. 2, the inverter 202 preferably includes a processor 220 in communication with memory 222, the processor for controlling: a gate driver 216 adapted to control a gate associated with each of the power transistors in the inverter; one or more built-in, on-board current sensors (or phase current sensors) 252 adapted to measure current in one or more of the phase current conductors 224, 226, and 228; and voltage sampling circuitry 208 adapted to sense/measure a junction voltage (or conduction voltage, or drain-source voltage (Vds) for MOSFETs, or collector-emitter voltage (Vce) or saturation voltage (Vce(sat)) for IGBTs) for one or more of the power transistors comprising the inverter. Also as shown, the voltage sampling circuitry/circuit 208 is preferably communicably associated with circuitry and/or software routines (e.g., computer instructions saved in memory 222, for example) that provide the functionality of an: isolation amplifier 210 adapted to amplify a sampled conduction voltage from the voltage sampling circuitry 208; filtering and gain 212 adapted to remove (filter) unwanted frequency content in the sampled conduction voltage data; peak detection 214 adapted to detect a peak conduction voltage; and communication 234 between the voltage sampling circuit 208 and processor 220, and/or communication 236 between circuitry and/or software/firmware associated with the isolation amplifier 210, filter and gain 212, and further circuitry and/or software functional blocks 214 such as a peak detector adapted to detect peak sampled voltage, a peak detector adapted to detect peak current amplitude sensed, and a sequencer adapted to reset each of the voltage and current peak detectors.

Different types of power semiconductors may be used in the inverter. For example, power transistor pairs 238, 240, and 242 may each comprise a pair of insulated-gate bipolar transistors (IGBTs). As another example, the power transistor pairs 238, 240, and 242 may each comprise a pair of metal-oxide semiconductor field effect transistors (MOSFETs). Further, a different number of power transistors may be used other than the six power transistors shown in FIG. 2. For instance, the inverter 202 may comprise additional power semiconductors configured in an additional three-phase bridge arrangement of six power transistors whereby the additional six switches may be adapted with load connections to exchange electrical energy between a generator or second motor, or to provide a different power configuration. For example, one group of six switches, i.e., pairs 238, 240, and 242, may be adapted to provide 50 kW power to a motor, and the other group of six switches, not shown, may be adapted to provide 30 kW power to a generator. As another example, an additional pair of power transistors may be arranged in a half-bridge and included in the inverter 202 so as to replace the connections from terminal 248 to connection point 230 and from terminal 250 to connection point 244, and configured so as to provide a half-bridge boost DC-DC converter from the battery to the inverter circuitry such as circuitry 204.

Next, FIG. 3 illustrates an exemplary power module 300 comprising a pair of power semiconductors 338 in a half-bridge arrangement, as may be used according to embodiments, and a temperature sensing element 322. The power module 300 may comprise, for example, a silicon carbide (SiC) power module model BSM250D17P2E004 available from Rohm Semiconductor having a pair 338 of MOSFETs arranged in a half-bridge, with each MOSFET comprising, as shown, a gate (G) adapted to control (using low voltage (gate driver) circuitry) current flow between a source (S) and a drain (D), an intrinsic diode (also called body diode) between the source and drain and a separate Schottky Barrier Diode also between the source and the drain (and in parallel with the Schottky diode) (to reduce switching losses). The current between source and drain (Ids) comprises a junction current; in a module, if multiple chips of MOSFETs are connected in parallel, the resulting Ids of the power switch is the sum of the multiple chips junction current. The voltage between source and drain (Vds) comprises a junction voltage. The on-state of the MOSFET comprises the conditions whereby, in response to (low voltage) input signals to the gate, the switch is in an on condition such that (high) current flows between the source and drain. An on-state resistance (Rds(on)) of the junction comprises the on-state junction voltage (or conduction voltage) divided by the on-state current or conduction current, or Rds(on)=Vds/Ids. The present inventors recognized that junction temperature (i.e., the temperature of the region between the gate, source, and drain, and represented schematically nearest to the arrow (representing, in this case, an n-channel MOSFET) in each of the MOSFET in the pair 338) may be estimated by measuring the temperature-dependent characteristic (e.g., Rds(on) in the case of a MOSFET, and Vce(sat) in the case of an IGBT), and then calculating the junction temperature (using a transfer function that relates the temperature-dependent characteristic to estimated junction temperature).

The present inventors determined, in the case of estimating a junction temperature of a power transistor, custom sampling circuitry 208 may be used to measure the on-state junction voltage, or conduction voltage, of the transistor. For example with respect to FIG. 3, voltage sampling circuitry 208 may comprise circuitry adapted to sense the voltage difference between drain pin 1 (reference 304) and source pin 3 (reference 308). The conduction current, in some embodiments, is available via a current sensor 252, which may be realized in any of a number of methods. Options for current sensing in automotive traction inverter applications may comprise, as examples, Hall-effect sensors, flux-gate sensors, current transformers, and/or shunt resistors. Phase current sensing for a traction motor such as motor 124 may comprise, for example, in-line motor phase current sensing accomplished using a shunt resistor, e.g., in phase current conductors 224, 226, and 228. The voltage drop across the shunt resistor is sensed by a sensor device with isolation so as to provide low voltage sensor signals (from the high voltage/high current phase current conductors) to the processor 220, whereby sensed conduction current (Ids) is calculated using a transfer function of the current sense signal.

As shown in FIG. 3, the pair 338 of MOSFETS include consecutively numbered pins/pinouts 1, 2, 3, 4 on the rights side, and 5, 6, 7, 8, 9 on the left side; and the NTC type thermistor 322 includes pins/pinouts 10 and 11. The NTC thermistor 322 comprises a pair of leads 320 and 318 and provides a resistance that decreases with increased temperature (of the region of the die proximate to the thermistor device/element). The thermistor, therefor, provides for sensing a temperature of the die (by using a processor to compute the temperature using a (non-linear) relationship between resistance and temperature).

One or more pair 338 of MOSFETs may be used in the inverter 202. For example, one or more of the pairs 238, 240, and 242 may each comprise a pair of power transistors 338 shown in a half-bridge arrangement of the power module 300. The half-bridge arrangement 206 in FIG. 2 may, for example, comprise the pair 338 shown in FIG. 3. In the exemplary module 300, all the pins on the left side (pins 7 (306), 9 (310), 8 (312), 6 (314), 5 (316)) are small current signals, connectable to the gate driver, and the pins on the right side comprise the power terminals, such as pin 1 (304). In such a configuration, the gates 310 and 314 may be electrically connected with gate driver 216; pin 306 is a low current pin and is used by the gate drive circuit; pin 1 on FIG. 3 is the power terminal and may be connected at 232 (inverter DC+link). Connection point 230 may differ from connection point 232, where 230 may comprise the DC power input of the inverter input and may be connected at 232 (DC+link bus in the inverter). Pin 324 may be connected to the gate driver. Pin 5 (reference 316) may be connected to the gate driver. Pin 2 (reference 324) may be connected with connecting point 246, and pin 3, 4 (reference 308) may be connected to motor (load) phase current conductor 224. An additional pair 338 may be similarly electrically connected for pairs 240 and 242, for connections to motor (load) phase current conductors 226 and 228, respectively. In this way, the inverter 202 may comprise six MOSFETs in a three-phase bridge arrangement so as to receive DC from the battery 130 and provide AC phase current to the motor 124.

As referenced above, a half-bridge boost DC-DC converter from the battery to the inverter circuitry 204 may be realized by replacing the connections from terminal 248 to connection point 230 and from terminal 250 to connection point 244, and inserting a pair of power transistors such as pair 338. For example, battery terminal 248 may be electrically connected with pin 8 (reference 312), and battery terminal 250 may be electrically connected with pin 5 (reference 316); and pin 1 (reference 304) may be electrically connected with connecting point 230, and pin 2 (reference 324) may be electrically connected with connecting point 244. In this way, DC from the battery terminals 248 and 250 is stepped up to DC delivered to inverter circuitry at connection points 230 and 244.

Turning now to FIG. 4, a perspective view of an inverter module 400 is shown, which depicts an arrangement of power transistors for an inverter according to embodiments, and that includes a discrete temperature sensing element 414. The discrete temperature sensing element 414 may comprise, for example, a thermistor, shown having a 3D cylindrical body with leads 434 and 432 extending opposite ends of the thermistor body. The leads 434 and 432 may be soldered to the board 430. Wire bonds 412 may connect to tabs extending from a ceramic substrate comprising the board.

The exemplary inverter module 400, as shown, comprises a case 424 having a top edge 436 opposite a bottom edge 438, establishing a depth (or height) of the case 424 that extends between 436 and 438. The case 424 is shown having a width between sides 440 and 442, and a length between reference 436 and reference 424. Within the case 424 are six similarly illustrated IGBTs 408, or more specifically six IGBT dies 408. Each IGBT includes emitter pads 406, or more specifically a pair of pads 406 for the IGBT collector and emitter. Each IGBT includes a gate pad 404. Diode dies 410 provide diodes for each of the IGBTs. The top surface of the board comprise a top bonded copper layer patterned with conductive paths for interconnection of the IGBTs and diodes. Also shown are exemplary pins, including, for example, power emitter pin 416, Kelvin gate pin 418, and Kelvin emitter pin 420.

FIG. 5 is a functional block diagram 500 showing exemplary components and methods for estimating junction temperature for an inverter design that includes a discrete sensing element. The measuring and processing steps comprise sensing temperature using a discrete sensing element such as the thermistor 414 in FIG. 4. The method includes providing a power semiconductor switch 502, such as a MOSFET switch, thermally coupled through a connection 504 to a (discrete) temperature sensing element 506. In some embodiments, the MOSFET switch 502 may be a high-voltage MOSFET, and the discrete temperature sensing element may be a thermistor or other discrete temperature sensing component of the inverter. This discrete temperature sensing element 506 is separately applied (e.g., by soldering) within the device. The discrete temperature sensing element comprise, for example, an NTC (negative temperature coefficient) thermistor, PTC (positive temperature coefficient) thermistor, or RTD (resistance temperature detector). Circuitry comprising the temperature sensing element is used to measure a temperature-dependent characteristic, for example, a resistance that varies with a change in temperature. Circuitry and/or software comprising an isolation amplifier 508 is then used to amplify the lower magnitude signals from the sensing element circuitry and provide galvanic isolation between the power electronics and the control electronics (processor side) of the inverter. Circuitry and/or software comprising filtering and gain 501 are then used to remove unwanted frequency content and further amplify (via filtering stages or processing to enhance signal gain. Next, a digital signal processor (DSP) 512 is used to calculate the estimated temperature using a transfer function 514 comprising a mathematical relationship between the measured temperature-dependent characteristic of the sensing element 506 (i.e. resistance) and temperature. And the result is a calculated estimated sensed/sensor temperature 516, which is then used for control of the MOSFET switch 502.

FIG. 6 is a functional block diagram 600 showing exemplary components and methods for estimating junction temperature for an inverter design, according to embodiments. The measuring and processing steps comprise a temperature estimation method for estimating a junction temperature of a power transistor comprising, first, measuring a temperature-dependent characteristic of a power semiconductor, and, second, estimating, using a processor, the junction temperature of the power semiconductor using a transfer function, wherein the transfer function comprises a mathematical relationship between junction temperature and the temperature-dependent characteristic of the power semiconductor, and wherein measurement of the temperature-dependent characteristic and estimation of the junction temperature therefrom is free from using a discrete sensing element.

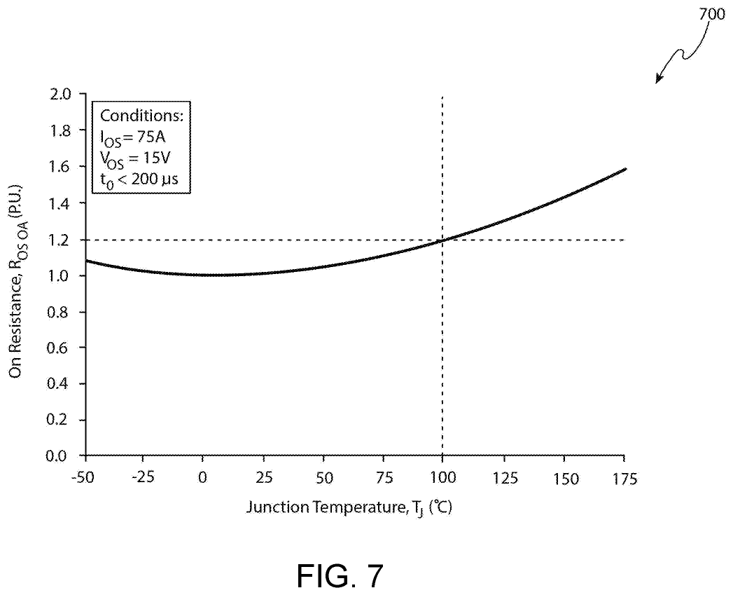

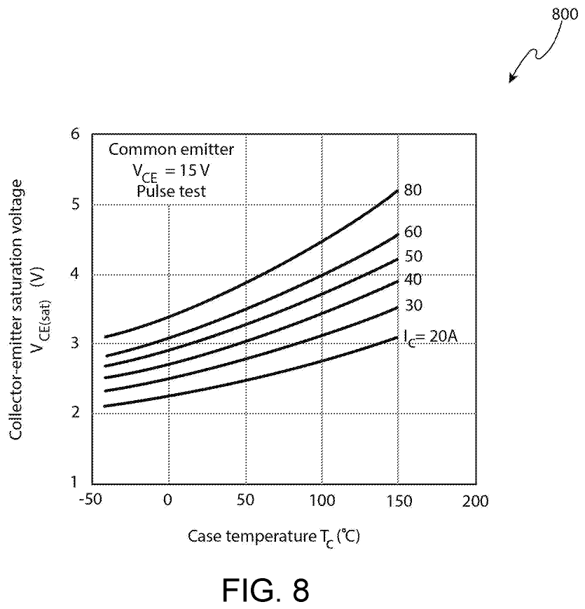

As shown in FIG. 6, a power semiconductor, or power semiconductor switch 602, is presented, in this case comprising a MOSFET switch 602. The junction voltage, or conduction voltage, or in the case of a MOSFET voltage between drain and source (Vds), or in the case of an IGBT saturation voltage between collector and emitter (Vce(sat)), is measured 604 using a custom designed voltage sampling circuit 208. The sampled conduction voltage (during on-time) 606 is then fed to or received by an isolation amplifier 210 (comprising circuitry and/or software) for increasing the magnitude of the sampled on-state voltage and provide galvanic isolation between the power electronics and the control electronics (DSP/processor side) of the inverter. The sampled voltage is enhanced through a filtering and gain 212 process whereby unwanted frequencies are removed and signal/data gain is improved (through filter stage gain or other processing/circuitry). A peak detector 214 (whether realized in circuitry or software) is used to detect peak conduction voltage 608, which is matched with a sequencer 618 to correspond with a peak current 620 from a peak detector 624 (whether realized in circuitry or software) adapted to detect a peak conduction current amplitude 622 from a current sensor 252. The sequencer 618 comprises a peak reset output signal (peak current detector reset) 626 to the peak (current) detector 624 and a peak reset output signal (peak voltage detector reset) 610 to the peak (voltage) detector 214, adapted to permit the peak conduction voltage 608 and the peak current 620 to be received by a transfer function 614 portion of a digital signal processor (DSP) 612. The transfer function 614 portion of the DSP uses the peak conduction voltage and peak current to estimate a junction temperature 616 of the power semiconductor 602. In the case of the power semiconductor comprising a MOSFET, the temperature-dependent characteristic comprises on-state junction resistance (calculated by the DSP as Rds(on)=Vds/Ids); and the relationship (transfer function) between on-state/on resistance versus junction temperature being representable in mathematical functions, such as for example the graph 700 in FIG. 7. In the case of the power semiconductor comprising an IGBT, the temperature-dependent characteristic comprises saturation voltage, or Vce(sat); and the relationship (transfer function) between on-state conduction voltage, or on-state collector-emitter voltage, or saturation voltage (Vce(sat) being representable in mathematical functions, such as for example the graph 800 in FIG. 8.

As shown in FIG. 6, the digital signal processor 612 may comprise a sequencer 618 and a transfer function 614. The DSP 612 may further comprise a peak detector 614 adapted to detect a peak current 620 from a current amplitude 622 from a current sensor 252. The DSP may, in some embodiments, comprise processor 220, and software associated with operation of the DSP functions, and calculations involving transfer function 614, may comprise programming routines and instructions, or software, or instructions saved in memory 222. In some embodiments, all or portions of the filtering and gain 212 may be realized in circuitry and/or software. Likewise, all or portions of the peak (voltage) detector 214, sequencer 618, transfer function 614, and/or peak (current) detector 624 may be realized in circuitry and/or software. The software may comprise computer-readable medium storing instructions that, when executed by a computer (such as processor 220), cause it to perform any or all of the methods described herein. The computer-readable medium may comprise, for example, read/write volatile or nonvolatile memory, such as memory 222.

The temperature estimation methods described herein do not rely on any discrete temperature sensing elements, but instead utilize measurement of a temperature-dependent characteristic of the power semiconductor. For MOSFETS, the temperature-dependent characteristic comprises an on-state resistance, and an exemplary transfer function/mathematical relationship between on-state resistance and junction temperature is shown in FIG. 7. For IGBTs, the temperature-dependent characteristic comprises saturation voltage (V_{CEsat}), and an exemplary transfer function/mathematical relationship between saturation voltage and junction temperature is shown in FIG. 8.

In the case of MOSFETs, the on-state resistance is calculated by measuring the conduction voltage of the device using a custom designed voltage sampling circuit and calculating the resistance using the current going through the MOSFET at that same time (measured with a current sensor). This temperature estimation method makes use of phase current sensor(s) used in high-power inverter designs. In some embodiments, the calculation of resistance is done in software by an embedded processor. The software then estimates the junction temperature using a known transfer function (junction temperature vs. on-state resistance). A similar procedure may be applied for IGBT devices, except for using a different transfer function (temperature vs. saturation (conduction) voltage). Since the conduction voltage corresponds directly to the semiconductor device temperature, the temperature measurement method described herein does not suffer from the inaccuracy and slow speed encountered with methods utilizing discrete sensing elements/remote resistive element temperature sensing.

Furthermore, with respect to FIG. 7, chart 700 presents one case of a potential transfer function as presented in FIG. 7, with Iₒₛ at 75 A, V_{gs} at 15 V, and tₚ less than 200 μs. With respect to this, the chart indicates that, for these particular parameters, at a junction temperature Tⱼ of 25° C., the transfer function would calculate the on-state resistance at approximately 1.0 P.U. At a junction temperature of 100° C., for the given parameters, the transfer function would calculate the on-state resistance at approximately 1.2 P.U. At a junction temperature of 150° C., for the given parameters, the transfer function would calculate the on-state resistance at approximately 1.4 P.U. It is to be understood that this transfer function is but one of a family of transfer functions that can relate junction temperature and on-state resistance with respect to a MOSFET.

With respect to FIG. 8 and chart 800, an example of a family of transfer functions that may be used to calculate V_{CE(sat)}. In this chart, the only parameter held constant is the common emitter voltage V_{GE}, which is kept at 15 V. Transfer functions are then presented for I_{c} at 20, 30, 40, 50, 60, and 80 A. For example, with respect to the transfer function for I_{c} at 20 A, a case temperature of 50° C. yields a saturation voltage of 2.5 V. With respect to the transfer function for I_{c} at 40 A, a case temperature of 50° C. yields a saturation voltage of 3 V. With respect to the transfer function for I_{c} at 60 A, a case temperature of 50° C. yields a saturation voltage of 3.5 V. Again, it is to be understood that a similar family of transfer functions exists for the relation between junction temperature and on-state resistance as presented in FIG. 8 and chart 800.

As described in detail herein, various embodiments are presented for sensing junction temperature of power transistors. In one embodiment, a temperature estimation method for estimating a junction temperature of a power transistor used in an electric vehicle inverter, the method comprises: measuring a temperature-dependent characteristic of a power semiconductor comprising the power transistor used in a power semiconductor module adapted for use in the electric vehicle inverter; and estimating, using a processor, the junction temperature of the power semiconductor using a transfer function, wherein the transfer function comprises a mathematical relationship between junction temperature and the temperature-dependent characteristic of the power semiconductor, wherein measurement of the temperature-dependent characteristic and estimation of the junction temperature therefrom is free from using a discrete sensing element. In one aspect, the temperature-dependent characteristic is an on-state resistance, and measuring the temperature-dependent characteristic comprises: sampling a junction voltage of the power transistor using a junction voltage sampling circuit; sensing a junction current of the power transistor using a phase current sensor; and calculating, using the processor, the on-state resistance using the junction current and the junction voltage. In one aspect, sampling the conduction voltage of the power transistor using the junction voltage sampling circuit includes measuring the voltage difference between a drain and a source of the power transistor during the on-time of the power transistor, sensing the junction current of the power transistor using the phase current sensor includes measuring the current between the drain and the source of the power transistor during the on-time of the power transistor, and the on-state resistance is the on-state resistance between the drain and the source of the power transistor and is calculated as the junction voltage divided by the junction current (or drain current in the case of a MOSFET). In one aspect, the power transistor is a MOSFET (metal-oxide semiconductor field effect transistor).

In one embodiment, the temperature-dependent characteristic is an on-state resistance, and measuring the temperature-dependent characteristic comprises: sensing a junction current of the power transistor using an on-state phase current sensor; detecting a peak current amplitude of the power transistor using a peak current detector; sampling a junction voltage of the power transistor using a junction voltage sampling circuit; detecting a peak conduction voltage using a peak voltage detector; and calculating, using a processor, the on-state resistance using the peak current amplitude and the peak conduction voltage. In one aspect, the peak current amplitude and the peak conduction voltage are matched with one another using a sequencer. In one aspect, sampling the junction voltage of the power transistor using the junction voltage sampling circuit includes measuring the voltage difference between a drain and a source of the power transistor during the on-time of the power transistor, sensing the junction current of the power transistor using the on-state phase current sensor includes measuring the drain current of the power transistor during the on-time of the power transistor, and the on-state resistance is the on-state resistance between the drain and the source of the power transistor and is calculated as the peak conduction voltage divided by the peak current amplitude. In one aspect, the power transistor is a MOSFET (metal-oxide semiconductor field effect transistor).

In one embodiment, the temperature-dependent characteristic is a saturation voltage of the power transistor, and measuring the temperature-dependent characteristic comprises: sampling the junction voltage of the power transistor using a junction voltage sampling circuit. In one aspect, sampling the junction voltage of the power transistor using the junction voltage sampling circuit includes measuring the voltage difference between a collector and an emitter of the power transistor during the on-time of the power transistor. In one aspect, the power transistor is an IGBT (insulated gate bipolar transistor).

In one embodiment, the temperature-dependent characteristic is a saturation voltage of the power transistor, and measuring the temperature-dependent characteristic comprises: sampling the junction voltage of the power transistor using a junction voltage sampling circuit; and detecting a peak saturation voltage using a peak voltage detector. In one aspect, the method further comprises: sensing a junction current of the power transistor using an on-state phase current sensor; detecting a peak current amplitude of the power transistor using a peak current detector; matching the peak current amplitude and the peak saturation voltage using a sequencer; and using the peak current amplitude and the peak saturation voltage to estimate the junction temperature of the power transistor based on the transfer function, wherein the transfer function includes junction temperature of the power transistor as a function of peak saturation voltage for the peak current amplitude or for a range of peak current amplitude that includes the peak current amplitude. In one aspect, sampling the junction voltage of the power transistor using the junction voltage sampling circuit includes measuring the voltage difference between a collector and an emitter of the power transistor during the on-time of the power transistor, and sensing the junction current of the power transistor using the on-state phase current sensor includes measuring the collector current of the power transistor during the on-time of the power transistor. In one aspect, the power transistor is an IGBT (insulated gate bipolar transistor). In other aspects, the power transistor may comprise SiC FETs or other types of transistors, which may benefit of the embodiments described herein.

In one embodiment, using the discrete sensing element includes the discrete sensing element being attached to a die surface comprising the power semiconductor or to a circuit board comprising the power semiconductor, and the discrete sensing element comprises one or more thermistor, NTC (negative temperature coefficient) thermistor, PTC (positive temperature coefficient) thermistor, or RTD (resistance temperature detector).

In another embodiment, a method for sensing a junction temperature of a power transistor used in an electric vehicle inverter comprises: sensing a junction current of the power transistor using a phase current sensor; detecting a peak current amplitude of the power transistor using a peak current detector; sampling a junction voltage of the power transistor using a junction voltage sampling circuit; detecting a peak conduction voltage using a peak voltage detector; calculating, using a processor, an on-state resistance using the peak current amplitude and the peak conduction voltage; and estimating the junction temperature using a transfer function that maps a predetermined relationship between junction temperature and on-state resistance, wherein the peak current amplitude and the peak conduction voltage are matched with one another using a sequencer, and wherein estimation of the junction temperature is free from using a discrete sensing element. In one aspect, the power transistor is a MOSFET (metal-oxide semiconductor field effect transistor), using the discrete sensing element includes the discrete sensing element being attached to a die surface comprising the MOSFET or to a circuit board comprising the MOSFET, and the discrete sensing element comprises one or more thermistor, NTC (negative temperature coefficient) thermistor, PTC (positive temperature coefficient) thermistor, or RTD (resistance temperature detector).

In another embodiment, a method for sensing a junction temperature of a power transistor used in an electric vehicle inverter comprises: sensing a junction current of the power transistor using an on-state phase current sensor; detecting a peak current amplitude of the power transistor using a peak current detector; sampling a junction voltage of the power transistor using a junction voltage sampling circuit; detecting a peak saturation voltage using a peak voltage detector; and estimating the junction temperature using a transfer function that maps a predetermined relationship between junction temperature and saturation voltage, wherein the peak current amplitude and the peak conduction voltage are matched with one another using a sequencer, and wherein estimation of the junction temperature is free from using a discrete sensing element. In one aspect, the power transistor is a IGBT (insulated gate bipolar transistor), using the discrete sensing element includes the discrete sensing element being attached to the power module substrate comprising the IGBT or to a circuit board comprising the IGBT, and the discrete sensing element comprises one or more thermistor, NTC (negative temperature coefficient) thermistor, PTC (positive temperature coefficient) thermistor, or RTD (resistance temperature detector).

In another embodiment, a system adapted to sense a junction temperature of a power transistor used in an electric vehicle inverter comprises: a junction voltage sampling circuit electrically interconnected with the power transistor in the electric vehicle inverter and adapted to sample a junction voltage of the power transistor to obtain a sampled junction voltage during an on-state of the power transistor; and a processor adapted to estimate the junction temperature of the power transistor based on the sampled junction voltage, wherein the system is free from a discrete temperature sensing element. In one aspect, the power transistor is a MOSFET (metal-oxide semiconductor field effect transistor), and the processor is adapted to calculate an on-state junction resistance of the MOSFET and estimate the junction temperature of the MOSFET based on the sampled junction voltage and calculated on-state junction resistance.

The technical effect of estimating junction temperature by measuring a temperature-dependent characteristic of a power semiconductor comprising the power transistor and estimating, using a processor, the junction temperature of the power semiconductor using a transfer function/mathematical relationship between junction temperature and the measured temperature-dependent characteristic, as described in detail herein, includes an inverter design that does not require or rely on discrete temperature sensing elements. The resulting inverter eliminates the need for the separate discrete temperature sensing element. This results in a more accurate and responsive method of acquiring temperature data for improved performance of the power inverter. For example, the motor control software embedded in the inverter could make use of the fast response of the temperature sensing method to allow a momentary overload of the inverter output current (i.e. providing more current to the motor) while ensuring that the power semiconductor switch junction temperatures are kept within acceptable limits.

As used in this application, an element or step recited in the singular and proceeded with the word “a” or “an” should be understood as not excluding plural of said elements or steps, unless such exclusion is stated. Furthermore, references to “one embodiment” or “one example” of the present disclosure are not intended to be interpreted as excluding the existence of additional embodiments that also incorporate the recited features. The terms “first,” “second,” and “third,” etc. are used merely as labels, and are not intended to impose numerical requirements or a particular positional order on their objects. The following claims particularly point out subject matter from the above disclosure that is regarded as novel and non-obvious.

Those having skill in the art will appreciate that there are various logic implementations by which processes and/or systems described herein can be affected (e.g., software), and that the preferred vehicle will vary with the context in which the processes are deployed. “Software” refers to logic that may be readily readapted to different purposes (e.g. read/write volatile or nonvolatile memory or media). The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood as notorious by those within the art that each function and/or operation within such block diagrams, flowcharts, or examples can be implemented, individually and/or collectively, by a wide range of hardware, software, firmware, or virtually any combination thereof.

It will be appreciated that the configurations and routines disclosed herein are exemplary in nature, and that these specific embodiments are not to be considered in a limiting sense, because numerous variations are possible. The subject matter of the present disclosure includes all novel and non-obvious combinations and sub-combinations of the various systems and configurations, and other features, functions, and/or properties disclosed herein.

The following claims particularly point out certain combinations and sub-combinations regarded as novel and non-obvious. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, are also regarded as included within the subject matter of the present disclosure.

1. A temperature estimation method for estimating a junction temperature of a power transistor used in an electric vehicle inverter, the method comprising:
measuring a temperature-dependent characteristic of a power semiconductor comprising the power transistor used in a power semiconductor module adapted for use in the electric vehicle inverter; and
estimating, using a processor, the junction temperature of the power semiconductor using a transfer function, wherein the transfer function comprises a mathematical relationship between junction temperature and the temperature-dependent characteristic of the power semiconductor, wherein measurement of the temperature-dependent characteristic and estimation of the junction temperature therefrom is free from using a discrete sensing element.

2. The method of claim 1, wherein the temperature-dependent characteristic is an on-state resistance, and measuring the temperature-dependent characteristic comprises:
sampling a junction voltage of the power transistor using a junction voltage sampling circuit;
sensing a junction current of the power transistor using a phase current sensor; and
calculating, using the processor, the on-state resistance using the drain current and the junction voltage.

3. The method of claim 2, wherein sampling the junction voltage of the power transistor using the junction voltage sampling circuit includes measuring the voltage difference between a drain and a source of the power transistor during the on-time of the power transistor, wherein sensing the drain current of the power transistor using the phase current sensor includes measuring the current flowing through the drain of the power transistor during the on-time of the power transistor, and wherein the on-state resistance is the on-state resistance between the drain and the source of the power transistor and is calculated as the junction voltage divided by the drain current.

4. The method of claim 3, wherein the power transistor is a MOSFET (metal-oxide semiconductor field effect transistor).

5. The method of claim 1, wherein the temperature-dependent characteristic is an on-state resistance, and measuring the temperature-dependent characteristic comprises:
sensing a drain current of the power transistor using a phase current sensor;
detecting a peak current amplitude of the power transistor using a peak current detector;
sampling a junction voltage of the power transistor using a junction voltage sampling circuit;
detecting a peak conduction voltage using a peak voltage detector; and
calculating, using a processor, the on-state resistance using the peak current amplitude and the peak conduction voltage.

6. The method of claim 5, wherein the peak current amplitude and the peak conduction voltage are matched with one another using a sequencer.

7. The method of claim 5, wherein sampling the junction voltage of the power transistor using the junction voltage sampling circuit includes measuring the voltage difference between a drain and a source of the power transistor during the on-time of the power transistor, wherein sensing the drain current of the power transistor using the phase current sensor includes measuring the current flowing through the drain of the power transistor during the on-time of the power transistor, and wherein the on-state resistance is the on-state resistance between the drain and the source of the power transistor and is calculated as the peak conduction voltage divided by the peak current amplitude.

8. The method of claim 7, wherein the power transistor is a MOSFET (metal-oxide semiconductor field effect transistor).

9. The method of claim 1, wherein the temperature-dependent characteristic is a saturation voltage of the power transistor, and measuring the temperature-dependent characteristic comprises:
sampling the junction voltage of the power transistor using a junction voltage sampling circuit.

10. The method of claim 9, wherein sampling the junction voltage of the power transistor using the junction voltage sampling circuit includes measuring the voltage difference between a collector and an emitter of the power transistor during the on-time of the power transistor.

11. The method of claim 10, wherein the power transistor is an IGBT (insulated gate bipolar transistor).

12. The method of claim 1, wherein the temperature-dependent characteristic is a saturation voltage of the power transistor, and measuring the temperature-dependent characteristic comprises:
sampling the junction voltage of the power transistor using a junction voltage sampling circuit; and
detecting a peak saturation voltage using a peak voltage detector.

13. The method of claim 12, further comprising:
sensing a collector current of the power transistor using a phase current sensor;
detecting a peak current amplitude of the power transistor using a peak current detector;
matching the peak current amplitude and the peak saturation voltage using a sequencer; and
using the peak current amplitude and the peak saturation voltage to estimate the junction temperature of the power transistor based on the transfer function, wherein the transfer function includes junction temperature of the power transistor as a function of peak saturation voltage for the peak current amplitude or for a range of peak current amplitude that includes the peak current amplitude.

14. The method of claim 13, wherein sampling the junction voltage of the power transistor using the junction voltage sampling circuit includes measuring the voltage difference between a collector and an emitter of the power transistor during the on-time of the power transistor, and wherein sensing the junction current of the power transistor using the phase current sensor includes measuring the current between the collector and the emitter of the power transistor during the on-time of the power transistor.

15. The method of claim 14, wherein the power transistor is an IGBT (insulated gate bipolar transistor).

16. The method of claim 1, wherein using the discrete sensing element includes the discrete sensing element being attached to a power module substrate comprising the power semiconductor or to a circuit board comprising the power semiconductor, and wherein the discrete sensing element comprises one or more thermistor, NTC (negative temperature coefficient) thermistor, PTC (positive temperature coefficient) thermistor, or RTD (resistance temperature detector).

17. A system adapted to sense a junction temperature of a power transistor used in an electric vehicle inverter, the system comprising:
a junction voltage sampling circuit electrically interconnected with the power transistor in the electric vehicle inverter and adapted to sample a junction voltage of the power transistor to obtain a sampled junction voltage during an on-state of the power transistor; and
a processor adapted to estimate the junction temperature of the power transistor based on the sampled junction voltage, wherein the system is free from a discrete temperature sensing element.

18. The system of claim 17, wherein the power transistor is a MOSFET (metal-oxide semiconductor field effect transistor), and the processor is adapted to calculate an on-state junction resistance of the MOSFET and estimate the junction temperature of the MOSFET based on the calculated on-state junction resistance.

19. A method for sensing a junction temperature of a power transistor used in an electric vehicle inverter, the method comprising:
sensing a junction current of the power transistor using a phase current sensor;
detecting a peak current amplitude of the power transistor using a peak current detector;
sampling a junction voltage of the power transistor using a junction voltage sampling circuit;
detecting a peak saturation voltage or a peak conduction voltage using a peak voltage detector; and
estimating the junction temperature using a transfer function that maps a predetermined relationship between junction temperature and the saturation voltage or the conduction voltage, wherein the peak current amplitude and the peak saturation voltage or the peak conduction voltage are matched with one another using a sequencer, and wherein estimation of the junction temperature is free from using a discrete sensing element.

20. The method of claim 19, wherein the power transistor is a IGBT (insulated gate bipolar transistor) or a MOSFET (metal-oxide field effect transistor), and wherein using the discrete sensing element includes the discrete sensing element being attached to a power module substrate comprising the IGBT or MOSFET, or to a circuit board comprising the IGBT or MOSFET, and wherein the discrete sensing element comprises one or more thermistor, NTC (negative temperature coefficient) thermistor, PTC (positive temperature coefficient) thermistor, or RTD (resistance temperature detector).
